(19) United States
(12) Patent Application Publication
(10) Pub. No.: US 2020/0395396 A1
(43) Pub. Date: Dec. 17, 2020

(54) IMAGE SENSOR PACKAGE

(71) Applicant: Samsung Electro-Mechanics Co., Ltd., Suwon-si (KR)

(72) Inventors: Do Jae YOO, Suwon-si (KR); Hye Ran WEE, Suwon-si (KR); Soon Kyo LEE, Suwon-si (KR); Jong Cheol HONG, Suwon-si (KR); Si Joong YANG, Suwon-si (KR)

(73) Assignee: Samsung Electro-Mechanics Co., Ltd., Suwon-si (KR)

(21) Appl. No.: 16/718,282

(22) Filed: Dec. 18, 2019

(30) Foreign Application Priority Data
Jun. 12, 2019 (KR) 10-2019-0069537

(51) Int. Cl. H01L 27/146

(52) U.S. Cl. CPC H01L 27/14625; H01L 27/14636

(57) ABSTRACT

An image sensor package includes a substrate; an image sensor connected to the substrate; a film member disposed on the substrate and defining a hole for exposing an effective image pickup surface of the image sensor; a bonding wire connecting the image sensor to the substrate; and a filter attached to the film member. The film member includes at least one void therein and at least a portion of the bonding wire is contained within the film member.

### CROSS-REFERENCE TO RELATED APPLICATION(S)

This application claims the benefit under 35 USC 119(a) of Korean Patent Application No. 10-2019-0069537 filed on Jun. 12, 2019 in the Korean Intellectual Property Office, the entire disclosure of which is incorporated herein by reference for all purposes.

### BACKGROUND

### 1. Field

The following description relates to an image sensor package.

### 2. Description of Background

In general, a camera module is applied to various devices such as portable electronic devices. Due to the trend for miniaturization of portable electronic devices in recent years, the miniaturization of a camera module itself is also required.

Meanwhile, an infrared cut-off filter is disposed in the camera module in order to block light in an infrared region.

In general, an additional device is used to fix an infrared cut-off filter or a structure capable of fixing an infrared cut-off filter to a housing is formed.

However, in such a manner, since the device for fixing the infrared cut-off filter is required, there may be a limitation in reducing an overall height of a camera module.

Portable electronic devices such as smartphones have been decreasing in thickness, but, it may be difficult to reduce a thickness of the smartphone if a height of a camera module is not also reduced.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

An image sensor package capable of satisfying demand for miniaturization.

In one general aspect, an image sensor package includes: a substrate; an image sensor connected to the substrate; a film member disposed on the substrate and defining a hole for exposing an effective image pickup surface of the image sensor; a bonding wire connecting the image sensor to the substrate; and a filter attached to the film member. The film member includes at least one void therein and at least a portion of the bonding wire is contained within the film member.

The at least one void may be disposed adjacent to the portion of the bonding wire contained within the film member.

The film member may cover a portion of the image sensor, and a size of the hole in a direction normal to an optical axis direction may be larger than a size of the effective image pickup surface of the image sensor in the direction normal to the optical axis direction, and may be smaller than a size of the image sensor in the direction normal to the optical axis direction.

An inner side surface of the film member defining the hole may be curved in a portion in which the filter contacts the film member and in a portion in which the image sensor contacts the film member.

The film member may include an inner side surface defining the hole, and the inner side surface of the film member may be rougher than other surfaces of the film member.

The image sensor package may include at least one electronic component mounted on the substrate, and the film member may include at least one groove formed on an outer side surface to prevent interference with the at least one electronic component.

The film member may include a step on an inner side surface defining the hole.

The inner side surface of the film member defining the hole may include a first surface, a second surface, and a third surface, formed along an optical axis direction. The second surface may connect the first surface to the third surface, and the third surface may be protruded further toward an optical axis than the first surface.

The second surface may be inclined.

A size of the hole in a direction normal to an optical axis direction may be larger on a first side of the step in the optical axis direction than a size of the hole in the direction normal to the optical axis direction on a second side of the step in the optical axis direction.

The film member may have a modulus of elasticity in a range of 100 Mpa to 2000 Mpa.

The image sensor package may include at least one electronic component mounted on the substrate and inserted into the film member, and the at least one void may be disposed adjacent to the electronic component and the portion of the bonding wire contained within the film member.

The film member may be spaced apart from the image sensor in an optical axis direction.

The film member may contact the image sensor along a surface of the image sensor that includes the effective image pickup surface.

An entirety of the bonding wire may be contained within the film member.

In another general aspect, an image sensor package includes: an image sensor; a substrate defining an accommodating space into which the image sensor is inserted; at least one electronic component disposed on the substrate; a bonding wire connecting the substrate to the image sensor; a film member disposed on the substrate such that at least a portion of the bonding wire and the at least one electronic component are contained within the film member, the film member defining a hole for exposing an effective image pickup surface of the image sensor; a filter attached to the film member; and a reinforcing plate coupled to the substrate to be in contact with the image sensor. At least one void may be provided inside the film member.

The at least one void may be disposed adjacent to the at least one electronic component and the portion of the bonding wire contained within the film member.

An inner side surface of the film member defining the hole may be rougher than other surfaces of the film member.

A size of the hole in a direction normal to an optical axis direction may be larger than a size of the image sensor in the direction normal to the optical axis direction, and may be smaller than a size of the accommodating space in the direction normal to the optical axis direction.

Other features and aspects will be apparent from the following detailed description, the drawings, and the claims.

### BRIEF DESCRIPTION OF DRAWINGS

FIG. 1 is a schematic cross-sectional view of a camera module according to an example.

FIG. 2 is a schematic cross-sectional view of an image sensor package according to an example.

FIGS. 3A to 3D are views illustrating a manufacturing process of an image sensor package according to an example.

FIGS. 4A and 4B are views illustrating a process of forming a hole in a film member.

FIG. 5 is a view illustrating a shape of an inner side surface of a film member in an image sensor package according to an example.

FIG. 6 is a schematic cross-sectional view of a camera module according to an example.

FIG. 7 is a plan view of a film member according to an example.

FIG. 8 shows a modified example of FIG. 7.

FIG. 9 is a schematic cross-sectional view of an image sensor package according to an example.

FIG. 10 is a schematic cross-sectional view of an image sensor package according to an example.

FIG. 11 is a schematic cross-sectional view of an image sensor package according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

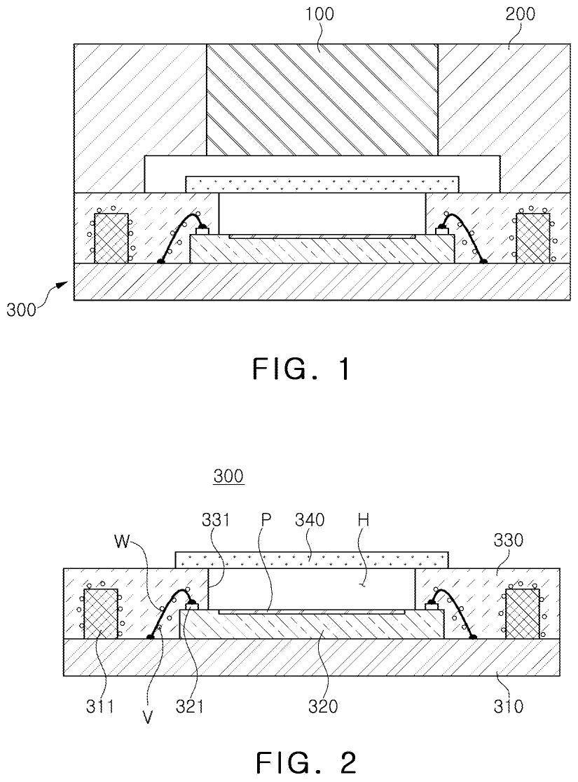

FIG. 1 is a schematic cross-sectional view of a camera module according to an example.

Referring to FIG. 1, a camera module includes a lens portion 100, a housing 200 and an image sensor package 300.

The lens portion 100 includes a plurality of lenses for imaging an object.

The housing 200 accommodates the lens portion 100, and may include an actuator (not illustrated) for moving the lens portion 100 in a direction of an optical axis and/or a direction perpendicular to the optical axis.

The image sensor package 300 is coupled to a lower portion of the housing 200. For example, the housing may be coupled to a film member 330 (see FIG. 2) as described below.

The image sensor package 300 may be provided as a device converting light incident through the lens portion 100 into an electrical signal.

As an example, as shown in FIG. 2, the image sensor package 300 includes a printed circuit board 310 (hereinafter, referred to as a ‘substrate’), an image sensor 320, a film member 330, and an infrared cut-off filter 340 (hereinafter, referred to as a ‘filter’).

FIG. 2 is a schematic cross-sectional view of an image sensor package according to an example.

Referring to FIG. 2, an image sensor package 300 includes a substrate 310, an image sensor 320, a film member 330, and a filter 340.

The image sensor 320 may convert light incident through the lens portion 100 into an electrical signal. As an example, the image sensor 320 may be a charge coupled device (CCD) or a complementary metal-oxide semiconductor (CMOS).

The electrical signal converted by the image sensor 320 may be output as an image through a display unit of a portable electronic device.

The image sensor 320 is electrically connected to the substrate 310 through a bonding wire W. The substrate 310 may be provided with at least one electronic component 311 mounted thereon.

The image sensor 320 is provided with an effective image pickup surface P receiving light to form an image, and a bonding pad 321 is formed on an outer side of the effective image pickup surface P. The bonding wire W is bonded to the bonding pad 321 to electrically connect the image sensor 320 to the substrate 310.

At least a portion of the bonding wire W is inserted into the film member 330.

The film member 330 is coupled to the substrate 310, and has a hole H for exposing the effective image pickup surface P of the image sensor 320.

At least a portion of the bonding wire W electrically connecting the image sensor 320 and the substrate 310 may be inserted into the film member 330.

The film member 330 may cover and seal a portion of the image sensor 320 and at least a portion of the bonding wire W. The film member 330 may cover and seal the electronic component 311.

According to an example, the electronic component 311 and an entire bonding wire W are inserted into the film member 330.

The bonding pad 321, to which the bonding wire W is bonded, is provided on an outer side of the effective image pickup surface P of the image sensor 320, and the film member 330 may cover and seal the bonding wire W and the bonding pad 321.

Thus, the bonding wire W may be protected by the film member 330. Accordingly, even when an external impact or the like is applied thereto, a problem in which the bonding wire W is cut or broken may be prevented.

Due to the film member 330, a foreign object, which may be generated from the bonding wire W, may be prevented from penetrating into the effective image pickup surface P of the image sensor 320.

The film member 330 may have a color capable of absorbing light. The film member 330 may have a color having low reflectance, for example, black.

Thus, undesired light in the camera module may be prevented from being incident on the effective image pickup surface P of the image sensor 320.

When light not necessary for image formation is incident on the effective image pickup surface P, a flare phenomenon and the like may be caused. However, in the case of the image sensor package 300 according to FIG. 2, due to the film member 330 being disposed around the effective image pickup surface P of the image sensor 320, unnecessary light may be prevented from being incident on the effective image pickup surface P.

The film member 330 is provided as an epoxy material, has a property of being a gel within a specific temperature range and being solidified within a different temperature range. The film member 330 may be formed to have a modulus of elasticity in a range of 100 Mpa to 2000 Mpa.

The film member 330 is provided with at least one void V therein. The void V may be formed around the bonding wire W inserted into the film member 330 and around the electronic component 311.

The void V provided inside the film member 330 may serve to buffer impacts transmitted to the bonding wire W and the electronic component 311 when an external impact or the like is applied.

The filter 340 may function to block light in an infrared region from light incident through the lens portion 100. The filter 340 is attached to the film member 330. As an example, the filter 340 may be attached to an upper surface of the film member 330 to be spaced apart from the image sensor 320 by a predetermined interval.

Generally, an additional device is used to fix the filter 340 or a structure, capable of fixing the filter 340 to the housing 200, is formed. However, in such a manner, since the device for fixing the filter 340 is required, there may be a limitation in reducing an overall height of a camera module.

Portable electronic devices such as smartphones have been decreasing in thickness, but it is difficult to reduce a thickness of the smartphone if a height of a camera module cannot be reduced.

However, in the image sensor package 300, since the filter 340 is mounted on the film member 330, an additional device for fixing the filter 340 is not required. Thus, a height of the image sensor package 300 itself may be reduced, and accordingly, a height of a camera module may be reduced.

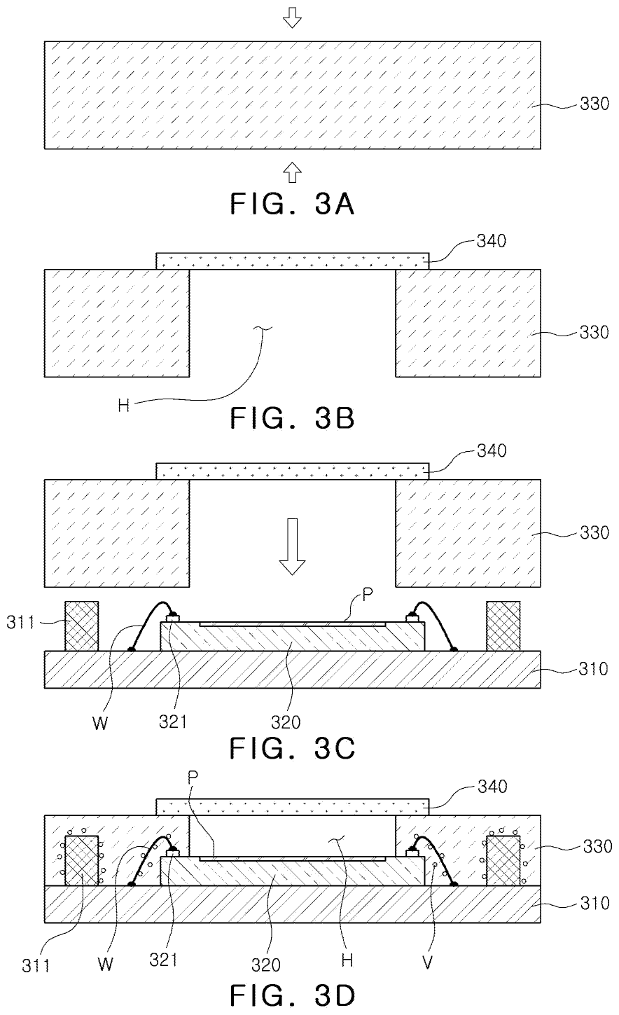

FIGS. 3A to 3D are views illustrating a manufacturing process of an image sensor package according to an example.

First, a hole H is formed in the film member 330 made of an epoxy material through punching. Punching may be performed in both directions as illustrated in FIG. 3A, but it is also possible to punch in one direction.

The film member 330 is coupled to the substrate 310 (see. FIG. 3C) after the filter 340 is attached to an upper surface of the film member 330 to cover the upper portion of the hole H (see. FIG. 3B).

Before the film member 330 is coupled to the substrate 310, at least one electronic component 311 and an image sensor 320 are mounted on the substrate 310, and the image sensor 320 and the substrate 310 are connected by a bonding wire W.

Since the film member 330 is a material having a gel form at a specific temperature range (for example, approximately 80°), at least a portion of the bonding wire W and the electronic component 311 may be inserted into the film member 330 in the course of coupling the film member 330 to the substrate 310.

At least one void V is formed around the bonding wire W and around the electronic component 311 in a process of inserting at least the bonding wire W and the electronic component 311 into the film member 330 (see FIG. 3D).

The void V formed inside the film member 330 may serve to buffer impacts transmitted to the bonding wire W and the electronic component 311 when there is an external impact, or the like.

When the film member 330 is coupled to the substrate 310, the film member 330 surrounds the effective image pickup surface P. That is, the film member 330 has a hole H for exposing the effective image pickup surface P.

A size of the hole H of the film member 330 may be larger than a size of the effective image pickup surface P of the image sensor 320, and may be smaller than the image sensor 320. Here, the size of the hole H may mean a size viewed from an optical axis direction.

Heat is applied to solidify the film member 330 after the film member 330 is bonded to the substrate 310.

As described above, in the image sensor package 300, since the filter 340 is coupled to the substrate 310 after the filter 340 is attached to the film member 330, an additional device for fixing the filter 340 is not required. Therefore, a height of the image sensor package 300 itself may be reduced, and accordingly, a height of the camera module may be reduced.

Since the bonding wire W and the electronic component 311 is inserted into the film member 330, the bonding wire W and the electronic component 311 may be protected when an external impact, or the like, is applied. Further, since the void V is provided inside the film member 330, an impact applied to the bonding wire W and the electronic component 311 may be buffered.

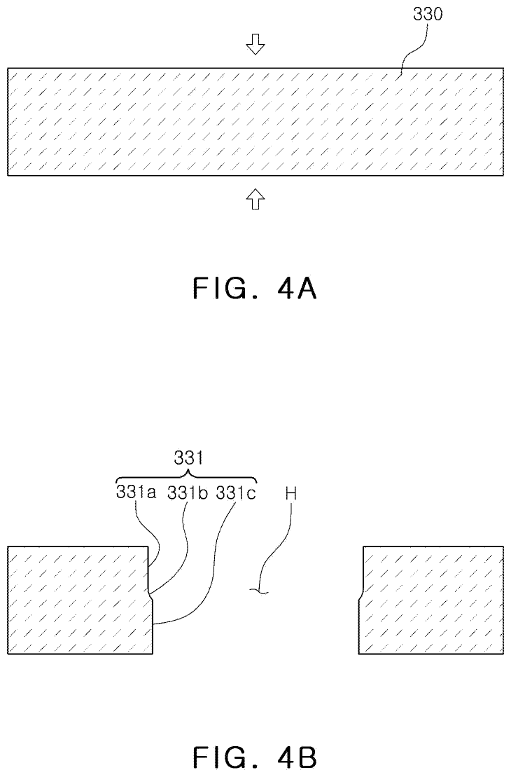

FIGS. 4A and 4B are views illustrating a process of forming a hole in a film member.

Referring to FIG. 4A, a hole H is formed in the film member 330 by punching the film member 330 in a direction toward an upper surface and a direction toward a lower surface, that is, in both directions.

Since the film member 330 is punched in both directions, a step is formed on an inner side surface 331 of the film member forming the hole H (see FIG. 4B).

For example, the inner side surface 331 of the film member 330 forming the hole H includes a first surface 331a, a second surface 331b, and a third surface 331c formed in an optical axis direction.

The first surface 331a and the third surface 331c may be vertical surfaces, and the second surface 331b may be an inclined surface connecting the first surface 331a and the third surface 331c. A step is formed on the inner side surface 331 of the film member 330 by the second surface 331b.

The third surface 331c may be a surface formed below the first surface 331a in the optical axis direction, and the third surface 331c may be a surface, protruded further into the hole H than the first surface 331a.

Therefore, the hole H of the film member 330 may be formed such that the size of the hole H upwardly in the optical axis direction is larger than downwardly in the optical axis direction.

The inner side surface 331 of the film member 330 may be formed to be rougher than other surfaces of the film member 330.

Accordingly, even if light is reflected from the inner side surface 331 of the film member 330, the reflected light may be scattered, thereby preventing a flare phenomenon from occurring.

Light penetrating through the lens portion 100 may be reflected by colliding with the inner side surface 331 of the film member 330 before being received by the image sensor 320. That is, even if the film member 330 is formed of a material having low reflectance, some light may be reflected. When this light is received in the image sensor 320, a flare phenomenon may be caused.

However, in the image sensor package 300, the inner side surface 331 of the film member 330 is formed to be rough to scatter the reflected light such that the reflected light may not be gathered at one point and accordingly, an occurrence of a flare phenomenon may be suppressed.

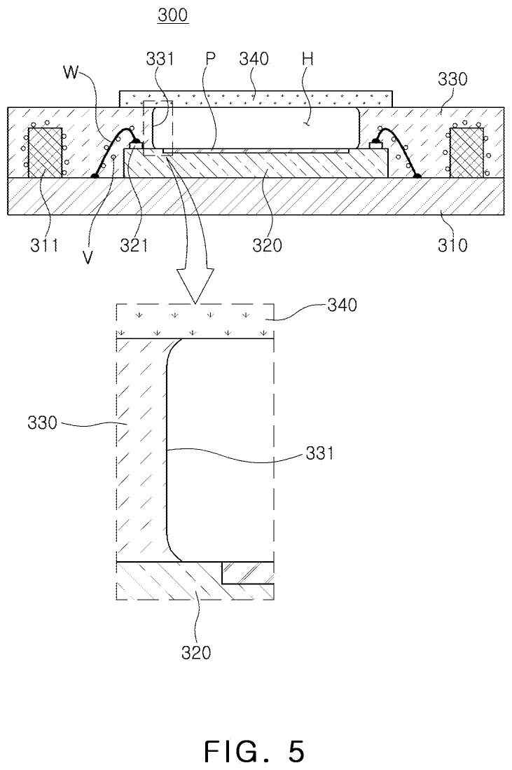

FIG. 5 is a view illustrating a shape of an inner side surface of the film member in the image sensor package according to an example.

Referring to FIG. 5, an upper portion of the inner side surface 331 of the film member 330 may be connected to the filter 340, and a lower portion of the inner side surface 331 of the film member 330 may be connected to the image sensor 320.

The upper and lower portions of the inner side surface 331 of the film member 330 may be curved surfaces having a curvature. Therefore, a bonding force at a bonding interface between the film member 330 and the filter 340 and at a bonding interface between the film member 330 and the image sensor 320 may be improved.

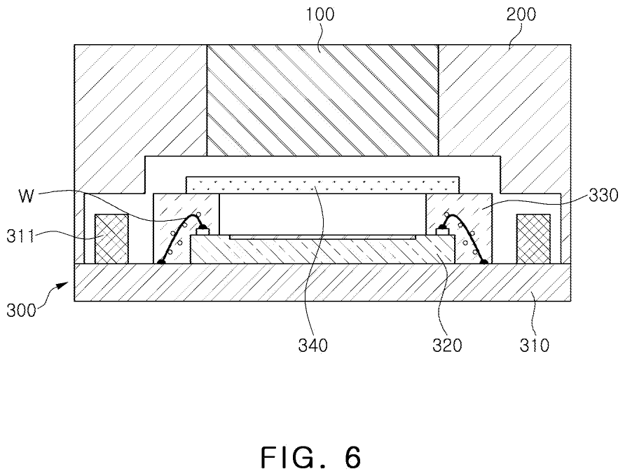

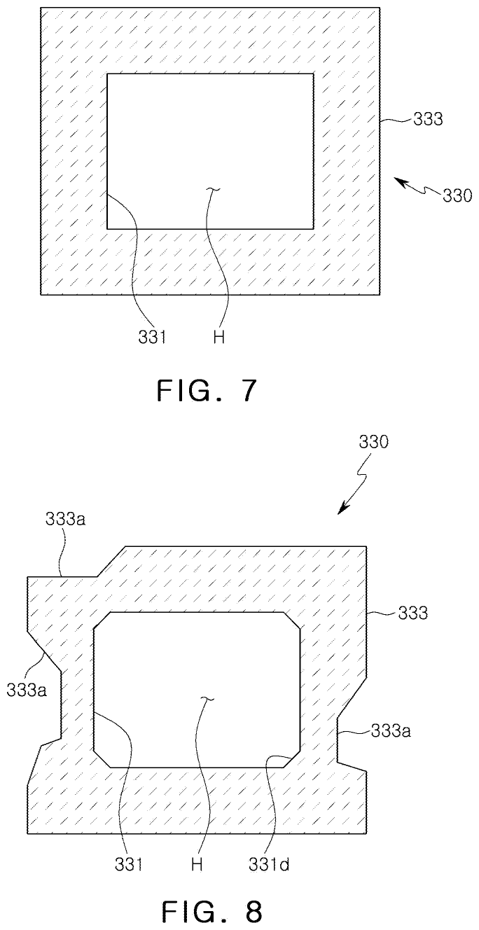

FIG. 6 is a schematic cross-sectional view of a camera module according to an example. FIG. 7 is a plan view of a film member according to an example, and FIG. 8 shows a modified example of FIG. 7.

An example according to FIG. 5 is the same as the camera module according to an example described above, except for a shape of the film member 330 and a coupling method of the housing 200 and the image sensor package 300.

Referring to FIG. 6, the image sensor package 300 is coupled to a lower portion of the housing 200. For example, the housing 200 may be coupled to the substrate 310.

The image sensor package 300 includes a substrate 310, an image sensor 320, a film member 330, and a filter 340.

The film member 330 may be coupled to the substrate 310 and the image sensor 320, and may have a hole H for exposing an effective image pickup surface P of the image sensor 320.

A bonding wire W is inserted into the film member 330, and at least one void V is formed inside the film member 330, that is, around the bonding wire W.

An electronic component 311 may be disposed outside of the film member 330.

Referring to FIG. 7, the inner side surface 331 of the film member 330, that is, the hole H may have a rectangular shape, and the outer side surface 333 of the film member 330 may also have a rectangular shape.

Referring to FIG. 8, at least one groove 333a may be formed on an outer side surface 333 of the film member 330 when viewed from an optical axis direction.

The outer side surface 333 of the film member 330 may be formed as a non-linear surface composed of a straight line and a curved line by at least one groove 333a.

At least one electronic component 311 is mounted on the substrate 310 and the electronic component 311 may be disposed on an outside of the film member 330, such that at least one groove 333a may be formed so as to prevent interference with the electronic component 311 on an outer side surface 333 of the film member 330.

A chamfered surface 331d may be provided in an edge region of the inner side surface 331 of the film member 330.

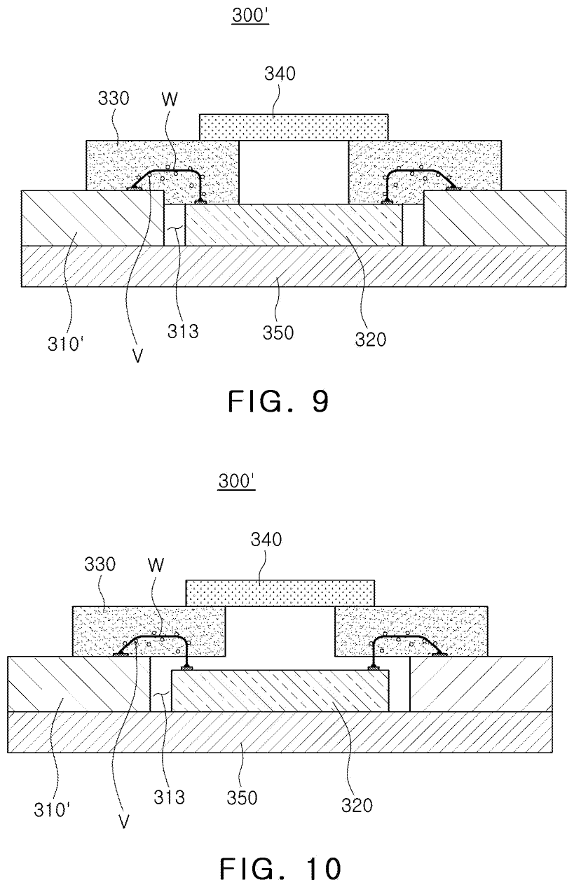

FIG. 9 is a schematic cross-sectional view of an image sensor package according to an example.

An image sensor package 300′ is the same as the image sensor package 300 described above except for a method by which the image sensor 320 is mounted on the substrate 310′.

Referring to FIG. 9, the substrate 310′ has an accommodating space 313 in which the image sensor 320 is accommodated. The accommodating space 313 may have a hole form penetrating through the substrate 310′.

The image sensor 320 may be inserted into and disposed in the accommodating space 313 of the substrate 310′. An upper surface of the image sensor 320 may be located below an upper surface of the substrate 310′.

Since the image sensor 320 is inserted into the accommodating space 313 of the substrate 310′, an overall height of the camera module may be reduced by a height of the image sensor 320 as compared with a case in which the image sensor is mounted on the upper surface of the substrate 310′.

The bonding wire W is inserted into the film member 330. Although not shown in FIG. 9, an electronic component is mounted on the substrate 310′, and the electronic component may also be inserted into the film member 330.

There may be a problem that the rigidity of the substrate 310′ is weakened since the accommodating space 313 having a hole form is provided in the substrate 310′, which may cause the substrate 310′ and the image sensor 320 to be damaged.

The image sensor package 300′ is provided with a reinforcing plate 350 to reinforce rigidity of the substrate 310′.

The reinforcing plate 350 may be made of a metal material and may be coupled to a lower portion of the substrate 310′.

Therefore, even if the accommodating space 313 having a hole form is provided in the substrate 310′, the rigidity is compensated by the reinforcing plate 350, such that it is possible to prevent the substrate 310′ and the image sensor 320 from being damaged during the manufacturing process and during use.

The reinforcing plate 350 may be thinner than the substrate 310′.

When the camera module is in used, heat is generated by the image sensor 320 which may cause degradation of resolution or noise in the captured image.

The image sensor package 300′ may be configured to easily radiate the heat generated by the image sensor 320.

For example, the image sensor 320 may be configured to be in contact with the reinforcing plate 350 while being inserted into the accommodating space 313 of the substrate 310′.

Since the reinforcing plate 350 is made of a thermally conductive material (for example, a metal material), heat generated in the image sensor 320 may be emitted to an outside through the reinforcing plate 350.

As described above, the heights of the image sensor package 300′ and the camera module may be reduced by inserting the image sensor 320 into the accommodating space 313 of the substrate 310′ and the rigidity of the substrate 310′ may be compensated by the reinforcing plate 350. The image sensor 320 may be in contact with the reinforcing plate 350, which is made of a metal material, such that the heat generated from the image sensor 320 may be easily emitted externally.

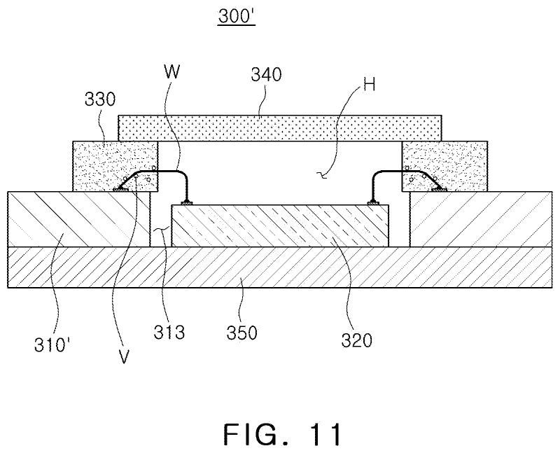

FIG. 10 is a schematic cross-sectional view of an image sensor package according to an example, and FIG. 11 is a schematic cross-sectional view of an image sensor package according to an example.

The image sensor package 300′ of FIGS. 10 and 11 is the same as the image sensor package 300′ described above except for a coupling method of the film member 330.

First, referring to FIG. 10, a portion of the bonding wire W is inserted into the film member 330, and a remainder of the bonding wire W may be exposed to an outside of the film member 330. Although not shown in FIG. 10, an electronic component may be mounted on the substrate 310′, and the electronic component may also be inserted into the film member 330.

Among the bonding wire W, a length of the bonding wire W inserted into the film member 330 may be longer than a length of the portion exposed to the outside of the film member 330.

The film member 330 may be coupled to the substrate 310′, and the film member 330 may be disposed to cover a portion of the upper surface of the image sensor 320.

A separation space is provided between the lower surface of the film member 330 and the upper surface of the image sensor 320 in an optical axis direction.

Referring to FIG. 11, a portion of the bonding wire W is inserted into the film member 330. Although not shown in FIG. 11, an electronic component may be mounted on the substrate 310′, and the electronic component may also be inserted into the film member 330.

The size of the hole H of the film member 330 may be larger than the size of the image sensor 320, and may be smaller than the size of the accommodating space 313 of the substrate 310′.

Through the above examples, an image sensor package may satisfy the demand for miniaturization.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An image sensor package, comprising:
a substrate;
an image sensor connected to the substrate;
a film member disposed on the substrate and defining a hole for exposing an effective image pickup surface of the image sensor, the film member comprising at least one void therein;
a bonding wire connecting the image sensor to the substrate, at least a portion of the bonding wire being contained within the film member; and
a filter attached to the film member.

2. The image sensor package of claim 1, wherein the at least one void is disposed adjacent to the portion of the bonding wire contained within the film member.

3. The image sensor package of claim 1, wherein the film member covers a portion of the image sensor, and
a size of the hole in a direction normal to an optical axis direction is larger than a size of the effective image pickup surface of the image sensor in the direction normal to the optical axis direction, and is smaller than a size of the image sensor in the direction normal to the optical axis direction.

4. The image sensor package of claim 3, wherein an inner side surface of the film member defining the hole is curved in a portion in which the filter contacts the film member and in a portion in which the image sensor contacts the film member.

5. The image sensor package of claim 1, wherein the film member comprises an inner side surface defining the hole, and
the inner side surface of the film member is rougher than other surfaces of the film member.

6. The image sensor package of claim 1, further comprising at least one electronic component mounted on the substrate, wherein the film member comprises at least one groove formed on an outer side surface to prevent interference with the at least one electronic component.

7. The image sensor package of claim 1, wherein the film member comprises a step on an inner side surface defining the hole.

8. The image sensor package of claim 7, wherein the inner side surface of the film member defining the hole includes a first surface, a second surface, and a third surface, formed along an optical axis direction,
wherein the second surface connects the first surface to the third surface, and
wherein the third surface is protruded further toward an optical axis than the first surface.

9. The image sensor package of claim 8, wherein the second surface is inclined.

10. The image sensor package of claim 7, wherein a size of the hole in a direction normal to an optical axis direction is larger on a first side of the step in the optical axis direction than a size of the hole in the direction normal to the optical axis direction on a second side of the step in the optical axis direction.

11. The image sensor package of claim 1, wherein the film member has a modulus of elasticity in a range of 100 Mpa to 2000 Mpa.

12. The image sensor package of claim 1, further comprising at least one electronic component mounted on the substrate and inserted into the film member,
wherein the at least one void is disposed adjacent to the electronic component and the portion of the bonding wire contained within the film member.

13. An image sensor package, comprising:
an image sensor;
a substrate defining an accommodating space into which the image sensor is inserted;
at least one electronic component disposed on the substrate;
a bonding wire connecting the substrate to the image sensor;
a film member disposed on the substrate such that at least a portion of the bonding wire and the at least one electronic component are contained within the film member, the film member defining a hole for exposing an effective image pickup surface of the image sensor;
a filter attached to the film member; and
a reinforcing plate coupled to the substrate and in contact with the image sensor,
wherein at least one void is provided inside the film member.

14. The image sensor package of claim 13, wherein the at least one void is disposed adjacent to the at least one electronic component and the portion of the bonding wire contained within the film member.

15. The image sensor package of claim 13, wherein an inner side surface of the film member defining the hole is rougher than other surfaces of the film member.

16. The image sensor package of claim 13, wherein a size of the hole in a direction normal to an optical axis direction is larger than a size of the image sensor in the direction normal to the optical axis direction, and is smaller than a size of the accommodating space in the direction normal to the optical axis direction.

17. The image sensor package of claim 1, wherein the film member is spaced apart from the image sensor in an optical axis direction.

18. The image sensor package of claim 1, wherein the film member contacts the image sensor along a surface of the image sensor that includes the effective image pickup surface.

19. The image sensor package of claim 1, wherein an entirety of the bonding wire is contained within the film member.
